(19) United States
(12) Patent Application Publication
(10) Pub. No.: US 2008/0180124 A1
(43) Pub. Date: Jul. 31, 2008

(54) COOLING APPARATUS FOR SEMICONDUCTOR DEVICE

(75) Inventor: Young Bae Chung, Seoul (KR)

Correspondence Address: Jason Y. Pahng and Associates, LLC, 12178 Bridgend Run, Fairfax, VA, 22030, US

(73) Assignee: ISC TECHNOLOGY CO., LTD., Seongnam (KR)

(21) Appl. No.: 12/019,642

(22) Filed: Jan. 25, 2008

(30) Foreign Application Priority Data
Jan. 31, 2007 (KR) 10-2007-0010130

(51) Int. Cl. G01R 31/26

(52) U.S. Cl. 324/760

(57) ABSTRACT

Provided is a cooling apparatus for a semiconductor device. The apparatus includes: a main body capable of moving vertically to face the semiconductor device that is mounted on a test unit in order to perform an electrical test; a heat exchange unit combined with the main body and contacting a top surface of the semiconductor device to absorb heat generated by the semiconductor device; and a lift unit combined with the main body and for moving the main body vertically. The heat exchange unit is combined with the main body to be capable of rotating according to an angle by which the semiconductor device is tilted when the heat exchange unit contacts the semiconductor device.

### CROSS-REFERENCE TO RELATED PATENT APPLICATION

This application claims the benefit of Korean Patent Application No. 10-2007-0010130, filed on Jan. 31, 2007, in the Korean Intellectual Property Office, the disclosure of which is incorporated herein in its entirety by reference.

### BACKGROUND OF THE INVENTION

1. Field of the Invention

The present invention relates to a cooling apparatus for a semiconductor device, and more particularly, to a cooling apparatus for a semiconductor device, the cooling apparatus having a thermal exchange unit that rotates according to a tilt angle of the semiconductor device and contacting a top surface of the semiconductor device with uniform contact pressure.

2. Description of the Related Art

Generally, in order to evaluate the performance of a semiconductor device, an electrical test is performed on the semiconductor device using a test apparatus. The electrical test is performed by supplying current to the semiconductor device after placing it on the test apparatus. During the test, when current is supplied to the semiconductor device, heat is generated in the semiconductor device. Thus, a cooling apparatus is provided in contact with the semiconductor device in order to absorb the generated heat and keep the semiconductor device at a constant temperature.

FIG. 1 illustrates a conventional cooling apparatus 100 for a semiconductor device. The cooling apparatus 100 includes a main body 110, a heat exchange unit 120, and a lift unit 130.

The main body 110 is installed opposite a semiconductor device 150 disposed on a test unit 160 and is capable of moving vertically. A supply tube 111 and an exhaust tube 112 are inserted into the main body 110 so that cooling water is supplied from an external cooling water supply unit 140 to the main body 110 and the cooling water is exhausted from the main body 110 to the external cooling water supply unit 140.

The heat exchange unit 120 is combined with the main body 110 and contacts a top surface 151 of the semiconductor device 150, thereby absorbing heat generated by the semiconductor device 150.

While cooling water supplied from the supply tube 111 is flowing through the heat exchange unit 120, the cooling water absorbs heat generated by the semiconductor device 150 and is exhausted through the exhaust tube 112.

The lift unit 130, which moves the main body 110 vertically, may be a linear motor or one of a hydraulic cylinder or a pneumatic cylinder having various shapes.

The cooling unit 100 having the above-described construction operates as follows.

Initially, the semiconductor device 150 is mounted on the test unit 160. Thereafter, the cooling apparatus 100 moves down until the heat exchange unit 120 is brought into contact with the top surface 151 of the semiconductor device 150. In this case, the lift unit 130 allows the heat exchange unit 120 of the cooling apparatus 100 to come into contact with the top surface 151 of the semiconductor device 150 with sufficient pressure. After that, current is supplied through the test unit 160 to the semiconductor device 150 so that a predetermined electrical test can be performed. Heat generated by the semiconductor device 150 is absorbed into the heat exchange unit 120. Specifically, cooling water flowing through the heat exchange unit 120 absorbs the heat and is then exhausted to the cooling water supply unit 140.

In the above-described process, the conventional cooling apparatus 100 can properly operate when the test unit 160 is completely disposed at the same level with a contact surface 121 of the heat exchange unit 120 that contacts the top surface 151 of the semiconductor device 150. However, when the test unit 160 is tiled by a predetermined angle as shown in FIG. 2, the operation of the cooling apparatus 100 is problematic.

Specifically, as shown in FIG. 3, when the cooling apparatus 100 is moved down to bring the top surface 151 of the semiconductor device 150 into contact with the contact surface 121 of the heat exchange unit 120, a portion (e.g., a left portion) of the contact surface 121 applies an excessive pressure to the top surface 151 of the semiconductor device 150, while another portion (e.g., a right portion) of the contact surface 121 applies an insufficient pressure to the top surface 151 of the semiconductor device 150 or cannot contact the top surface 151 of the semiconductor device 150.

In addition, a portion of the semiconductor device 150 contacts the test unit 160 with excessive pressure, while another portion of the semiconductor device 150 contacts the test unit 160 with weak pressure.

Since the heat exchange unit 120 contacts the semiconductor device 150 with nonuniform pressure, heat generated by the semiconductor device 150 cannot be sufficiently transmitted to the heat exchange unit 120. Also, an electrical connection of the semiconductor device 150 with the test unit 160 is unstable.

### SUMMARY OF THE INVENTION

The present invention provides a cooling apparatus for a semiconductor device, wherein the cooling apparatus can sufficiently absorb heat generated by the semiconductor device even if the semiconductor device is inclined.

According to an aspect of the present invention, there is provided a cooling apparatus for a semiconductor device. The cooling apparatus includes: a main body capable of moving vertically to face the semiconductor device that is mounted on a test unit in order to perform an electrical test; a heat exchange unit combined with the main body and contacting a top surface of the semiconductor device in order to absorb heat generated by the semiconductor device; and a lift unit combined with the main body in order to move the main body vertically. The heat exchange unit is combined with the main body to be capable of rotating according to an angle at which the semiconductor device is tilted when the heat exchange unit contacts the semiconductor device.

The heat exchange unit rotates about a contact point located on a contact surface of the heat exchange unit that contacts the semiconductor device.

The heat exchange unit comprises: a pair of first guide pins disposed on an axis parallel to a first axis which penetrates the contact point; and a first sliding curved surface having a center of curvature located on the first axis. And the main body comprises: a first guide slot hole in which the first guide pins are partially inserted, the first guide slot hole having a first inner curved surface with a center of curvature located on the first axis; and a second sliding curved surface having the same center of curvature as the first sliding curved surface and disposed further from the center of curvature.

A first bearing is mounted between the first sliding curved surface and the second sliding curved surface to be in rolling contact with the first sliding curved surface and the second sliding curved surface.

A pair of second guide pins disposed on a axis parallel to a second axis which is orthogonal to the first axis and penetrates the contact point and located on the contact surface; and a third sliding curved surface having a center of curvature located on the second axis. And the main body comprises: a second guide slot hole in which the second guide pins are partially inserted, the second guide slot hole having a second inner curved surface with a center of curvature located on the first axis; and a fourth sliding curved surface having the same center of curvature as the third sliding curved surface and disposed further from the center of curvature.

A second bearing is mounted between the third sliding curved surface and the fourth sliding curved surface to be in rolling contact with the third sliding curved surface and the fourth sliding curved surface.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of a conventional cooling apparatus for a semiconductor device;

FIGS. 2 and 3 illustrate a case where the cooling apparatus shown in FIG. 1 is in contact with a semiconductor device when the semiconductor device is inclined;

FIG. 4 is a perspective view of a cooling apparatus for a semiconductor device according to an embodiment of the present invention;

FIG. 5 is an exploded perspective view of the cooling apparatus shown in FIG. 4;

FIG. 6 is a side view of the cooling apparatus shown in FIG. 4;

FIG. 7a and 7b illustrate a case where the cooling apparatus shown in FIG. 4 is in contact with a semiconductor device when the semiconductor device is inclined in a X axial direction; and

FIGS. 8a and 8b illustrate a case where the cooling apparatus shown in FIG. 4 is in contact with a semiconductor device when the semiconductor device is inclined in a Y axial direction.

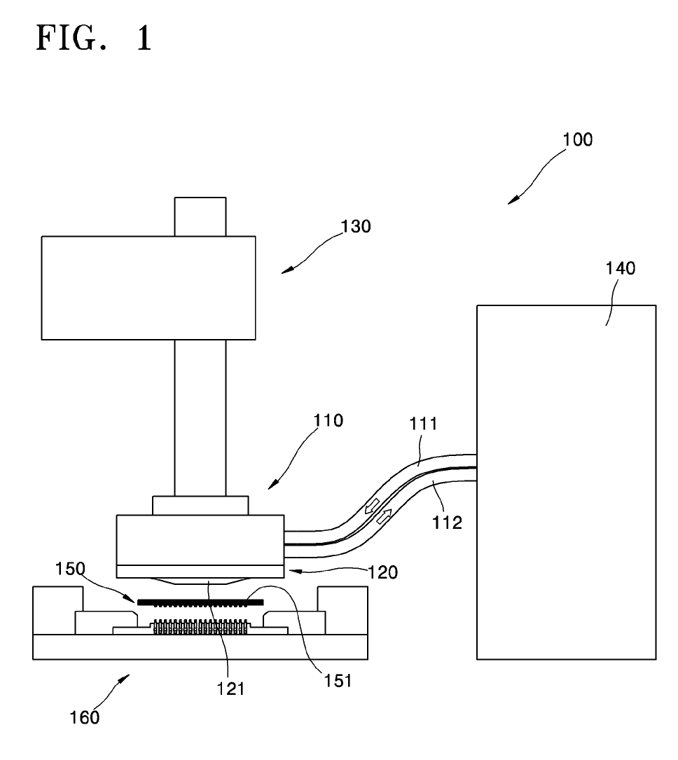

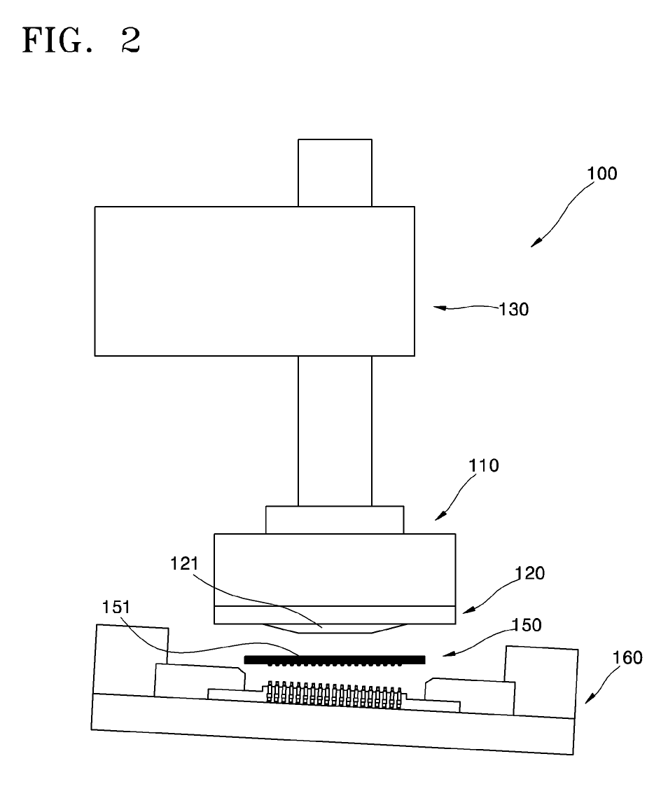

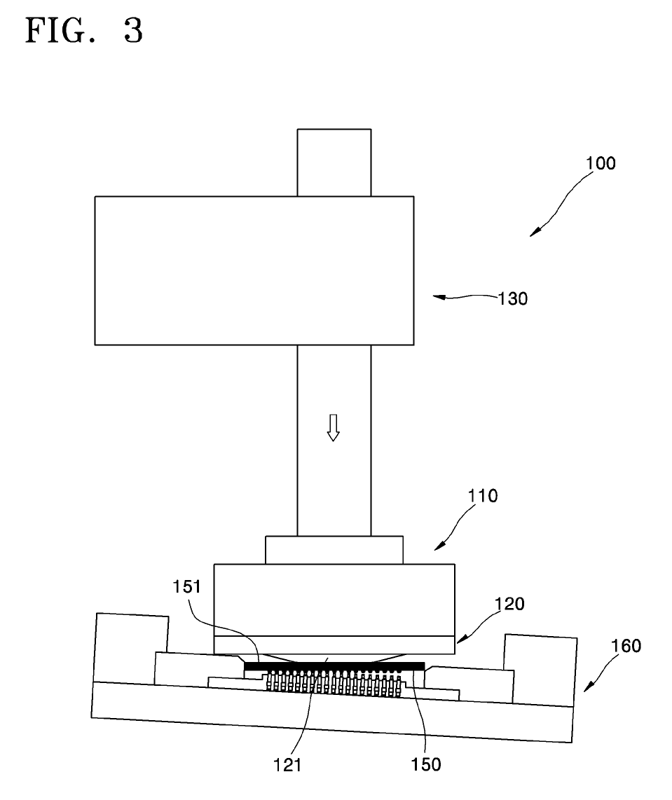

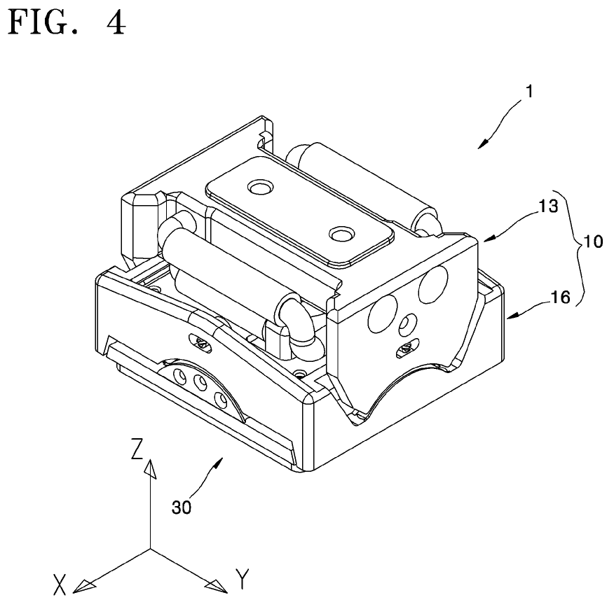

### DETAILED DESCRIPTION OF THE INVENTION

The cooling apparatus 1 for the semiconductor device 60 includes a main body 10, a heat exchange unit 30, and a lift unit 40.

The main body 10 is capable of moving vertically to face the semiconductor device 60 that is mounted on a test unit in order to perform an electrical test. And the heat exchange unit 30 is combined with the main body 10 and contacting a top surface of the semiconductor device 60 to absorb heat generated by the semiconductor device 60. And the lift unit 40 combined with the main body 10 and moving the main body 10 vertically. The heat exchange unit 30 is combined with the main body 10 to be capable of rotating according to an angle by which the semiconductor device 60 is tilted when the heat exchange unit 30 contacts the semiconductor device 60. And the heat exchange unit 30 rotates about a contact point located on a contact surface 33 of the heat exchange unit 30 that contacts a top surface 61 of the semiconductor device 60.

The main body 10 is installed opposite the semiconductor device 60, which is mounted on a test unit in order to perform an electrical test, and can move vertically.

The main body 10 includes a first guide slot hole 11 and a second sliding curved surface 12.

A pair of first guide pin 31 of the heat exchange unit 30, which will be described later, are partially inserted into the first guide slot hole 11. And the first guide slot hole 11 have a first inner curved surface with a center of curvature located on a first axis which penetrates the contact point.

The second sliding curved surface 12 has the same center of curvature as a first sliding curved surface 32, which will be described later. The second sliding curved surface 12 is disposed further from the center of curvature.

The heat exchange unit 30, which is combined with the main body 10, contacts the top surface 61 of the semiconductor device 60 and absorbs heat generated by the semiconductor device 60.

When the heat exchange unit 30 contacts the semiconductor device 60, the heat exchange unit 30 is combined with the main body 10 to be capable of rotating according to an angle at which the semiconductor device 60 is tilted.

The heat exchange unit 30 includes the pair of first guide pins 31 and the first sliding curved surface 32.

The pair of first guide pins 31 are fixed detachably to an axis parallel to the first axis which penetrates the contact point. The first guide pins 31 are partially inserted into the first guide slot hole 11 and move along the first inner curved surface of the first guide slot hole 11. Since the first guide pins 31 are inserted into the first guide slot hole 11, even if the cooling apparatus 1 moves vertically, the heat exchange unit 30 is not detached from the main body 10 and can remain combined with the main body 10.

The first sliding curved surface 32 is prepared in the heat exchange unit 30 such that the center of curvature of the first sliding curved surface 32 is located on the first axis.

A first bearing 80 is mounted between the second sliding curved surface 12 and the first sliding curved surface 22 to be in rolling contact with the second sliding curved surface 12 and the first sliding curved surface 22.

The lift unit 40 includes a linear motor 41 and a lift shaft 42 that moves vertically due to the operation of the linear motor 41. The lift shaft 42 is combined with the main body 10 and moves the main body 10 vertically due to the operation of the linear motor 41.

In the cooling apparatus 1 having the above-described construction, the heat exchange unit 30 may rotate about the contact point, as will be described in detail later.

In the current embodiment, the main body 10 includes an upper main body 13 and a rotation unit 16 so that the rotation unit 16 can rotate about the upper main body 13.

Hereinafter, the upper main body 13 and the rotation unit 16 of the main body 10 will be described.

The upper main body 13 is combined with the lift unit 40. The upper main body 13 includes a second guide slot hole 14 and a fourth sliding curved surface 15.

A pair of second guide pins 17 of the rotation unit 16, which will be described later, are partially inserted into the second guide slot hole 14. And the second guide slot hole 14 have a second inner curved surface with a center of curvature located on a second axis which is orthogonal to the first axis and penetrates the contact point.

The fourth sliding curved surface 15 has the same center of curvature as a third sliding curved surface 18 of the rotation unit 16, which will be described later. The fourth sliding curved surface 15 is disposed further from the center of curvature.

When the heat exchange unit 30 contacts the semiconductor device 60, the rotation unit 16 is combined with the upper main body 13 to be capable of rotating according to an angle at which the semiconductor device 60 is tilted.

The rotation unit 16 includes the pair of second guide pins 17 and the third sliding curved surface 18.

The pair of second guide pin 17 are fixed detachably to a axis parallel to a second axis which is orthogonal to the first axis and penetrates the contact point and located on the contact surface. The second guide pins 17 are partially inserted into the second guide slot hole 14 and move along the second inner curved surface of the second guide slot hole 16.

The third sliding curved surface 18 is prepared in the rotation unit 16 such that the center of curvature of the third sliding curved surface 18 is located on the second axis.

A second bearing 81 is mounted between the third sliding curved surface 18 and the fourth sliding curved surface 15 to be in rolling contact with the third sliding curved surface 18 and the fourth sliding curved surface 15.

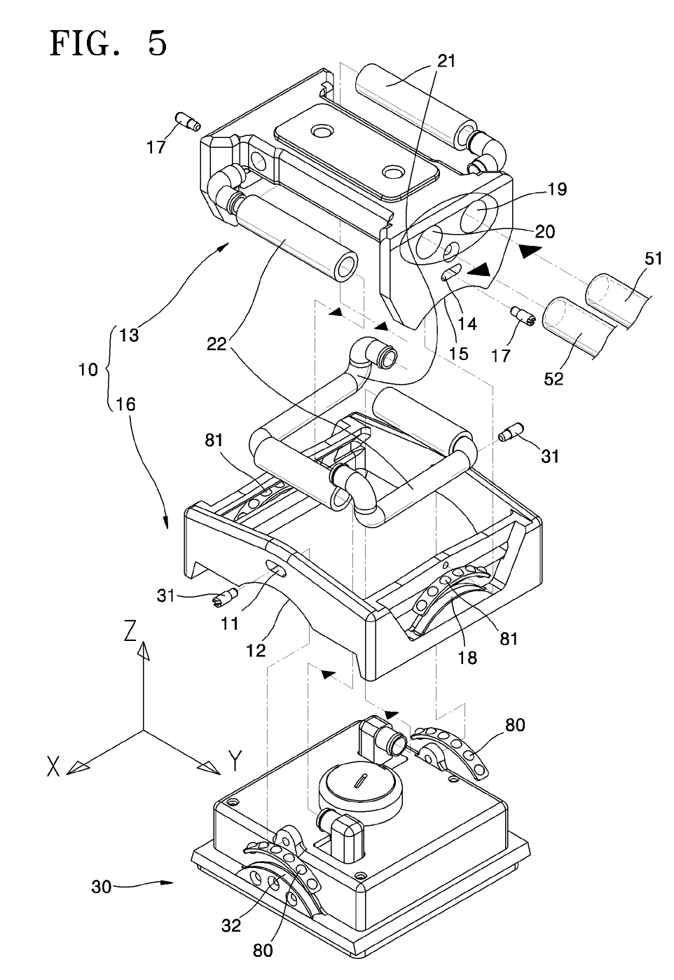

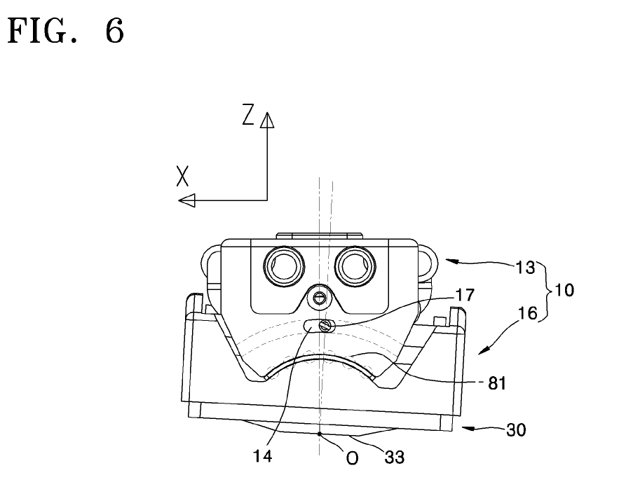

Referring to FIGS. 5 through 8, the cooling apparatus 1 further includes an inlet port 19, an outlet port 20, a supply tube 21, and an exhaust tube 22.

The inlet port 19 is prepared in the main body 10 and allows cooling water to be supplied from a cooling water supply unit (not shown) to the main body 10. A supply pipe 51 is connected to the cooling water supply unit and inserted into the inlet port 19.

The outlet port 20 is prepared in the main body 10 and allows the cooling water to be exhausted from the main body 10. An exhaust pipe 52 is connected to the cooling water supply unit and inserted into the inlet port 19.

The supply tube 21 guides cooling water supplied via the inlet port 19 to the heat exchange unit 30. Although the whole supply tube 21 may be formed of an elastic material, for example, rubber, a portion of the supply tube 21 may be formed of rubber and the other portion thereof may be formed of a metal or a hard material. When the heat exchange unit 30 is brought into contact with the tilted semiconductor device 60, the heat exchange unit 30 rotates at a predetermined angle with the main body 10. Therefore, by forming only a portion of the supply tube 21 using an elastic material, for example, rubber, the heat exchange unit 30 can rotate smoothly. However, when the entire supply tube 21 is formed of a hard material, the rotation of the main body 10 and the heat exchange unit 30 is restricted by the supply tube 21.

The exhaust tube 22 guides cooling water exhausted via the heat exchange unit 30 outside the main body 10. Like the supply tube 21, at least a portion of the exhaust tube 22 may be formed of an elastic material, such as rubber.

The above-described cooling apparatus 1 for the semiconductor device 60 has the following function.

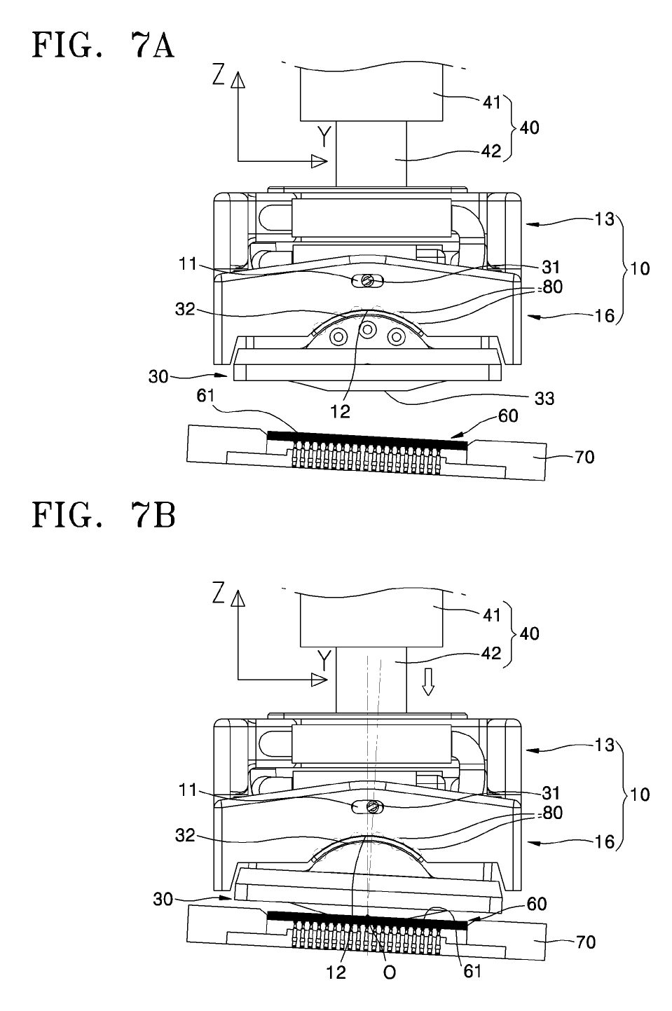

When the semiconductor device 60 is mounted on the test unit 70 to perform an electrical test as shown in FIG. 7a, the lift unit 40 is driven until the contact surface 33 of the heat exchange unit 30 is closely contacted by the top surface 61 of the semiconductor device 60 with sufficient pressure.

In this case, when the semiconductor device 60 is tilted at an angle in the X-axial direction, the contact surface 33 of the heat exchange unit 30 contacts the top surface 61 of the semiconductor device 50 and simultaneously rotates as shown in FIG. 7b. The heat exchange unit 30 rotates until the contact surface 33 becomes parallel to the top surface 61 of the semiconductor device 60, and then stops. Thereafter, the contact surface 33 of the heat exchange unit 30 is closely contacted by the top surface 61 of the semiconductor device 60 with sufficient pressure.

Since the contact surface 33 of the heat exchange unit 30 remains parallel to the top surface 61 of the semiconductor device 60, the heat exchange unit 30 can contact the top surface 61 of the semiconductor device 60 with uniform pressure. Thus, heat generated by the semiconductor device 60 can be sufficiently absorbed in the cooling apparatus 1. Also, the semiconductor device 60 can be electrically stably combined with the test unit 70.

Meanwhile, the heat exchange unit 30 rotates about contact point positioned on the contact surface 33 of the heat exchange unit 30. The rotation of the heat exchange unit 30 will now be described in detail.

Initially, when the contact surface 33 of the heat exchange unit 30 is brought into contact with the top surface 61 of the tilted semiconductor device 60, the first guide pins 31 fixed to the heat exchange unit 30 move along the first inner curved surface of the first guide slot hole 11. Simultaneously, the first sliding curved surface 32 is in rolling contact with the bearing 80 and moves relative to the second sliding curved surface 12.

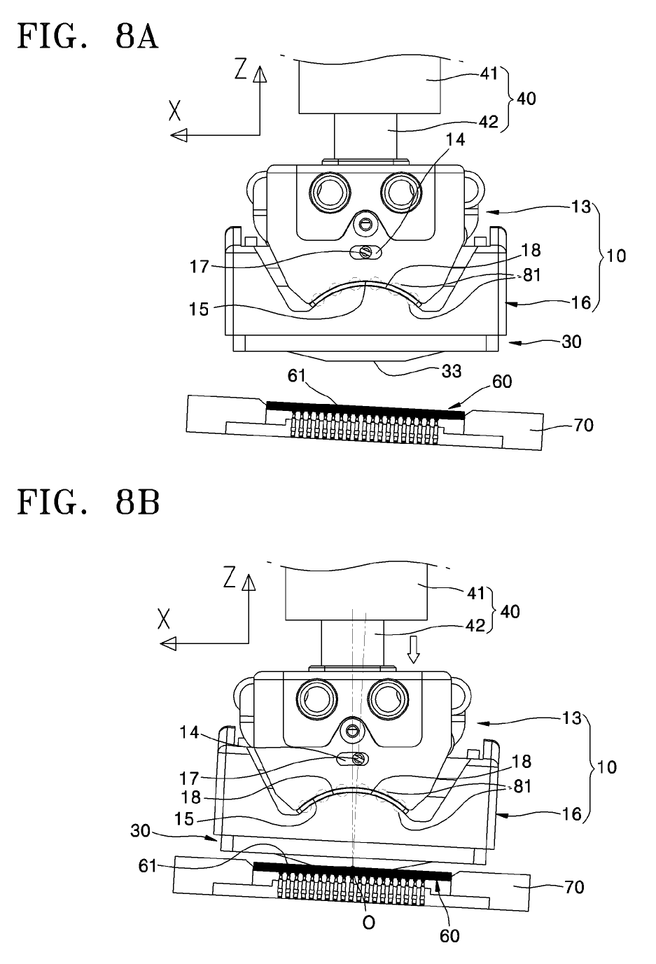

When the semiconductor device 60 is tilted in the Y-axial direction orthogonal to the the X-axial direction as shown in FIG. 8a, the rotation unit 16 rotates by the same angle as the tilt angle of the semiconductor device 60. In this case, the rotation unit 16 stops rotating when the contact surface 33 of the heat exchange unit 30 rotates parallel to the top surface 61 of the semiconductor device 60 as shown FIG. 8b. Thereafter, a sufficient pressure is applied to the contact surface 33 of the heat exchange unit 30 so that the contact surface 33 of the heat exchange unit 30 is closely contacted by the top surface 61 of the semiconductor device 60.

Similarly, since the contact surface 33 of the heat exchange unit 30 contacts the top surface 61 of the semiconductor device 60 with uniform pressure, heat generated by the semiconductor device 50 can be sufficiently absorbed in the cooling apparatus 1.

Meanwhile, the rotation unit 16 rotates such that the contact point is on the contact surface 33 of the heat exchange unit 30. The rotation of the rotation unit 16 will now be described in detail.

Initially, when the contact surface 33 of the heat exchange unit 30 is brought into contact with the top surface 61 of the tilted semiconductor device 60, the second guide pins 17 fixed to the rotation unit 16 move along the second inner curved surface of the second guide slot hole 14. Simultaneously, the third sliding curved surface 18 is in rolling contact with the bearing 80 and moves relative to the fourth sliding curved surface 15.

When the contact surface 33 of the heat exchange unit 30 is completely brought into contact with the top surface 61 of the semiconductor device 60 in the above-described manner, current is supplied from the test unit 70 to the semiconductor device 60 to perform an electrical test. Simultaneously, heat generated by the semiconductor device 60, and the cooling water supply unit supplies cooling water via the supply pipe 51 to the inlet port 19 of the main body 10. The cooling water supplied to the inlet port 19 flows via the supply tube 21 into the heat exchange unit 30. While the cooling water is flowing through the heat exchange unit 30, it absorbs heat transmitted from the semiconductor device 60. After the cooling water absorbs a sufficient amount of heat, it flows via the exhaust tube 22 to the outlet port 20. Thereafter, the cooling water is exhausted from the outlet port 20 via the exhaust pipe 52 to the cooling water supply unit.

The cooling apparatus 1 for the semiconductor device 60 according to the current embodiment of the present invention has the following advantages.

In a conventional cooling apparatus for a semiconductor device, since a contact surface of a heat exchange unit does not rotates according to a tilt angle of the semiconductor device, the contact area of the heat exchange unit cannot be in contact with a top surface of the semiconductor device with uniform pressure. Thus, heat generated by the semiconductor device cannot be sufficiently transmitted to the heat exchange unit. Also, the semiconductor device cannot be electrically stably contacted by the test unit.

In contrast, in the cooling apparatus for a semiconductor device according to the present embodiment, the contact surface of the heat exchange unit can rotate according to a tilt angle of the semiconductor device, so that the contact surface of the heat exchange unit can always contact a top surface of the semiconductor device with uniform pressure. Thus, heat generated by the semiconductor device can be sufficiently transmitted to the heat exchange unit. Also, the semiconductor device can be electrically stably contacted by the test unit.

Furthermore, in the cooling apparatus for a semiconductor device according to the present embodiment, the heat exchange unit or the rotation unit includes a contact point positioned on the contact surface of the heat exchange unit. Thus, even if the heat exchange unit or the rotation unit rotates when the contact surface of the heat exchange unit contacts the top surface of the semiconductor device, the semiconductor device does not slide due to the heat exchange unit. In contrast, when the contact point of the heat exchange unit or the rotation unit is positioned on the top or bottom of the heat exchange unit instead of the contact surface thereof, while the heat exchange unit or the rotation unit is rotating when the contact surface of the heat exchange unit contacts the top surface of the semiconductor device, the semiconductor device is pushed by the contact surface of the heat exchange unit and slides. As described above, when the semiconductor device moves vertically to face the test unit, it is difficult to maintain a stable electrical and mechanical contact of the semiconductor device with the test unit, and the lifetime of the test unit is degraded.

In variations of the current embodiment, the cooling apparatus for a semiconductor device may be modified as follows.

Although the above embodiment describes that both the heat exchange unit and the rotation unit rotate, only a heat exchange unit may rotate in only one axial direction. In this case, an upper main body and a rotation unit may be replaced by a single main body.

As compared with the above embodiment in which the rotation unit rotates in a direction orthogonal to a rotation direction of the heat exchange unit, another embodiment may provide a cooling apparatus in which a rotation unit rotates in the same direction as a heat exchange unit or a cooling apparatus in which a rotation unit rotates in various axial directions according to circumstances.

In the above embodiment, the bearings may be mounted between the first and second sliding curved surfaces and between the third and fourth sliding curved surfaces, however it is also possible that the first and second sliding curved surfaces contact each other and move relative to each other and the third and fourth sliding curved surfaces contact each other and move relative to each other without the bearings. In this case, each of the first through fourth sliding curved surfaces may be coated or previously impregnated with a lubricant to allow each of the first through fourth sliding curved surfaces to move smoothly.

Also, the above embodiment describes that the heat exchange unit includes the first guide pins and the main body includes the first guide slot hole, but the present invention is not limited thereto. In other words, the main body may include the first guide pins and the heat exchange unit may include the first guide slot hole. Similarly, unlike in the above embodiment, the upper main body may include the second guide pins and the rotation unit may include the second guide slot hole.

Furthermore, the above embodiment describes that the first guide pins are detachably attached to the heat exchange unit and the second guide pins are detachably attached to the rotation unit. However, an integral protrusion may be used instead of the first and second guide pins. Also, the first and second guide slot holes may be replaced by grooves so as to form rotation paths.

In the above-described cooling apparatus for a semiconductor device according to the present invention, even if the semiconductor device is inclined, the heat exchange unit can contact a top surface of the semiconductor device in parallel, so that the entire surface of the heat exchange unit can contact the top surface of the semiconductor device with uniform pressure. As a result, heat generated by the semiconductor device can be sufficiently transmitted to the heat exchange unit.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A cooling apparatus for a semiconductor device, comprising:
a main body capable of moving vertically to face the semiconductor device that is mounted on a test unit in order to perform an electrical test;
a heat exchange unit combined with the main body and contacting a top surface of the semiconductor device to absorb heat generated by the semiconductor device; and
a lift unit combined with the main body and moving the main body vertically,
wherein the heat exchange unit is combined with the main body to be capable of rotating according to an angle by which the semiconductor device is tilted when the heat exchange unit contacts the semiconductor device.

2. The apparatus of claim 1, wherein the heat exchange unit rotates about a contact point located on a contact surface of the heat exchange unit that contacts the semiconductor device.

3. The apparatus of claim 2, wherein the heat exchange unit comprises:
a pair of first guide pins disposed on an axis parallel to a first axis which penetrates the contact point; and
a first sliding curved surface having a center of curvature located on the first axis,
and wherein the main body comprises:
a first guide slot hole in which the first guide pins are partially inserted, the first guide slot hole having a first inner curved surface with a center of curvature located on the first axis; and
a second sliding curved surface having the same center of curvature as the first sliding curved surface and disposed further from the center of curvature.

4. The apparatus of claim 3, wherein a first bearing is mounted between the first sliding curved surface and the second sliding curved surface to be in rolling contact with the first sliding curved surface and the second sliding curved surface.

5. The apparatus of claim 3, wherein the rotation unit comprises:
a pair of second guide pins disposed on a axis parallel to a second axis which is orthogonal to the first axis and penetrates the contact point and located on the contact surface; and
a third sliding curved surface having a center of curvature located on the second axis,
and wherein the main body comprises:
a second guide slot hole in which the second guide pins are partially inserted, the second guide slot hole having a second inner curved surface with a center of curvature located on the first axis; and
a fourth sliding curved surface having the same center of curvature as the third sliding curved surface and disposed further from the center of curvature.

6. The apparatus of claim 5, wherein a second bearing is mounted between the third sliding curved surface and the fourth sliding curved surface to be in rolling contact with the third sliding curved surface and the fourth sliding curved surface.
